(19) United States
(12) Patent Application Publication
(10) Pub. No.: US 2026/0140163 A1
(43) Pub. Date: May 21, 2026

(54) CHIP PROBING APPARATUS, CHIP PROBING METHOD AND SHIFT DETECTION PATTERN

(71) Applicant: Taiwan Semiconductor Manufacturing Company, Ltd., Hsinchu (TW)

(72) Inventors: Tien-Yu Cheng, Kaohsiung City (TW); Cheng-Han Huang, Hsinchu (TW); Jian-Ting Chen, Hsinchu County (TW)

(73) Assignee: Taiwan Semiconductor Manufacturing Company, Ltd., Hsinchu (TW)

(21) Appl. No.: 18/953,096

(22) Filed: Nov. 20, 2024

(51) Int. Cl. G01R 31/28; G01R 1/073

(52) U.S. Cl. CPC G01R 31/2831; G01R 1/07342

(57) ABSTRACT

A chip probing apparatus, adapted to perform a chip probing process of a wafer is provided. The wafer includes integrated circuit regions, scribe line regions and at least one shift detection pattern distributed in the scribe line regions. The chip probing apparatus includes a probe card including electrical measurement needles and shift detection needles, wherein the electrical measurement needles are adapted to be pressed onto the integrated circuit regions, and the shift detection needles are adapted to be pressed onto the shift detection pattern. The at least one shift detection pattern includes a target probing pattern and an auxiliary pattern distributed in proximity to the target probing pattern, and one of the shift detection needles is pressed onto the target probing pattern and the auxiliary pattern simultaneously when the probe card is misaligned with the wafer.

### BACKGROUND

High performance computing (HPC) devices with high pin counts is popular. To ensure fabrication yield of the HPC devices, a chip probing process is needed. The chip probing process may suffer misalignment issue due to the temperature difference between the probe card (about 75 Celsius degrees) and the wafer including HPC devices (about 105 Celsius degrees). Probing shift (about 20 micrometers) resulted from the coefficient of thermal expansion (CTE) difference between the probe card and the wafer will cause tip burnt or yield loss. Currently, there is no solution to detect probing shift smaller than 20 micrometers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A schematically illustrates a cross-sectional view of a chip probing apparatus for performing a chip probing process on a wafer in accordance with some embodiments of the present disclosure.

FIG. 1B schematically illustrates a top view of a wafer including a shift detection pattern in accordance with some embodiments of the present disclosure.

FIG. 2A schematically illustrates a top view of a shift detection pattern when the shift detection needles are properly aligned in accordance with the first embodiment of the present disclosure.

FIG. 2B and FIG. 2C schematically illustrate top views of a shift detection pattern when the shift detection needle is misaligned in accordance with the first embodiment of the present disclosure.

FIG. 3A schematically illustrates a top view of a shift detection pattern when the shift detection needles are properly aligned in accordance with the second embodiment of the present disclosure.

FIG. 3B and FIG. 3C schematically illustrate top views of a shift detection pattern when the shift detection needle is misaligned in accordance with the second embodiment of the present disclosure.

FIG. 4A schematically illustrates a top view of a shift detection pattern when the shift detection needles are properly aligned in accordance with the third embodiment of the present disclosure.

FIG. 4B through FIG. 4D schematically illustrate top views of a shift detection pattern when the shift detection needle is misaligned in accordance with the third embodiment of the present disclosure.

FIG. 5A schematically illustrates a top view of a shift detection pattern when the shift detection needles are properly aligned in accordance with the fourth embodiment of the present disclosure.

FIG. 5B through FIG. 5D schematically illustrate top views of a shift detection pattern when the shift detection needle is misaligned in accordance with the fourth embodiment of the present disclosure.

FIG. 6A schematically illustrates a top view of a shift detection pattern when the shift detection needles are properly aligned in accordance with the fifth embodiment of the present disclosure.

FIG. 6B through FIG. 6D schematically illustrate top views of a shift detection pattern when the shift detection needle is misaligned in accordance with the fifth embodiment of the present disclosure.

FIG. 7 schematically illustrates a cross-sectional view of the target probing pattern in accordance with the fifth embodiment of the present disclosure.

### DETAILED DESCRIPTION

It is to be understood that the following disclosure provides many different embodiments, or examples, for implementing different features of the disclosure. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the performance of a first process before a second process in the description that follows may include embodiments in which the second process is performed immediately after the first process, and may also include embodiments in which additional processes may be performed between the first and second processes. Various features may be arbitrarily drawn in different scales for the sake of simplicity and clarity. Furthermore, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. For example, if the device in the figures is turned over, elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

In addition, terms, such as “first”, “second”, “third”, “fourth”, and the like, may be used herein for ease of description to describe similar or different element(s) or feature(s) as illustrated in the figures, and may be used interchangeably depending on the order of the presence or the contexts of the description. Throughout the various views and illustrative embodiments, like reference numbers are used to designate like elements.

In accordance with some embodiments, a probe card with electrical measurement needles and shift detection needles is used in a chip probing process of a wafer. Furthermore, a shift detection pattern is formed on the wafer (e.g., scribe line regions of the wafer) to facilitate the detection of alignment shift between the probe card and the wafer. A first testing signal is applied from a test head to the shift detection pattern through the shift detection needles to obtain a probing shift information. A second testing signal is applied from a test head to integrated circuit regions of the wafer through the electrical measurement needles to obtain a chip probing information when the probing shift information shows that the probe card is aligned with the wafer. The probe card with electrical measurement needles and shift detection needles and the shift detection pattern provides good wafer probing quality gating by electric testing, for example, a probing shift smaller than about 12 micrometers can be detected. Furthermore, the probe card with electrical measurement needles and shift detection needles and the shift detection pattern can identify shift amount and shift direction between the wafer and the probe card.

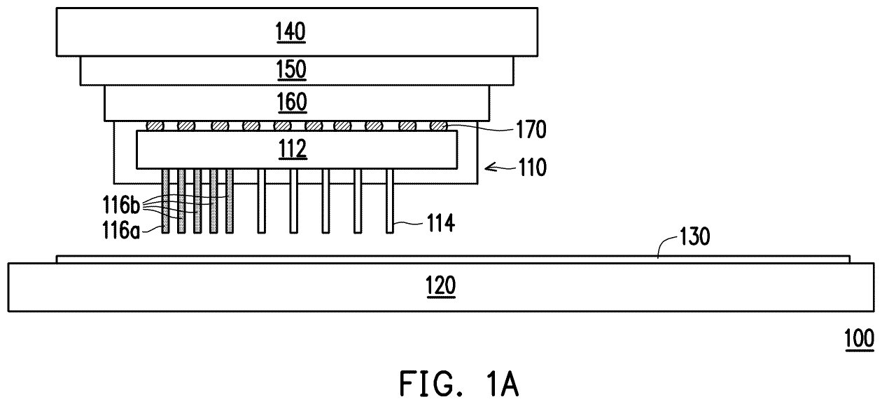

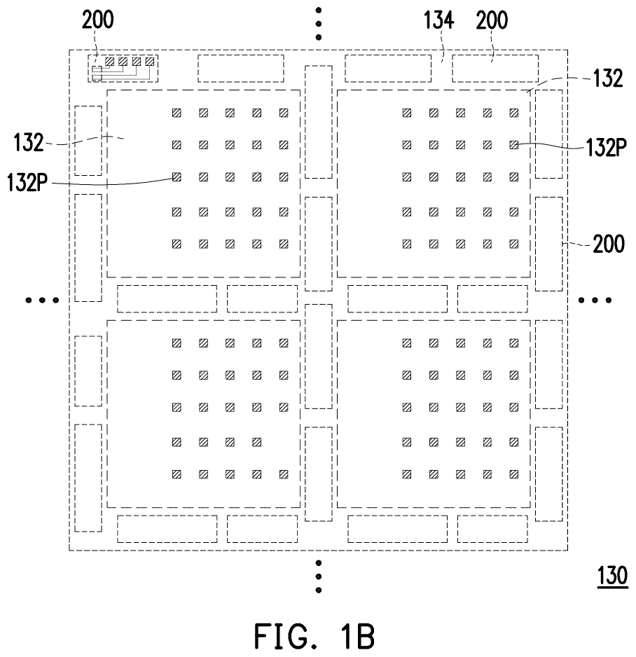

FIG. 1A schematically illustrates a cross-sectional view of a chip probing apparatus for performing a chip probing process on a wafer in accordance with some embodiments of the present disclosure, and FIG. 1B schematically illustrates a top view of a wafer including a shift detection pattern in accordance with some embodiments of the present disclosure.

Referring to FIG. 1A, a chip probing apparatus 100 including a probe card 110 and a wafer stage 120 disposed under the probe card 110 is provided, wherein a wafer 130 is disposed on the wafer stage 120 and located between the wafer stage 120 and the probe card 110. The probe card 110 includes a substrate 112, electrical measurement needles 114 and shift detection needles 116a and 116b, wherein the electrical measurement needles 114 and the shift detection needles 116a and 116b protrude from the bottom surface of the substrate 112, and the electrical measurement needles 114 and the shift detection needles 116a and 116b are electrically connected to the substrate 112.

In some embodiments, as illustrated in FIG. 1A, the probe card 110 of the chip probing apparatus 100 is movably installed over the wafer stage 120 such that the relative position between the probe card 110 and the wafer stage 120 can change through the movement of the probe card 110. In some other embodiments, the wafer stage 120 of the chip probing apparatus 100 is movably installed under the probe card 110 such that the relative position between the probe card 110 and the wafer stage 120 can change through the movement of the wafer stage 120. In some alternative embodiments, the probe card 110 and the wafer stage 120 of the chip probing apparatus 100 are both movably installed such that the relative position between the probe card 110 and the wafer stage 120 can change through the movement of the probe card 110 and the movement of the wafer stage 120.

The wafer 130 to be inspected by a chip probing process is placed on the wafer stage 120. In some embodiments, the wafer 130 is a semiconductor wafer including semiconductor substrate and an interconnect structure disposed on and electrically connected to the semiconductor substrate, wherein the material of the semiconductor substrate may be or include silicon, silicon germanium, germanium, silicon carbon, aluminum nitride, gallium arsenide, boron nitride, silicon nitride, beryllium oxide, indium arsenide, indium gallium arsenide, indium antimonide, or the like. In some other embodiments, the substrate 100 is a bulk mono-crystalline silicon substrate, an epitaxial silicon layer on a silicon wafer, a silicon-on-insulator (SOI) wafer, a germanium-on-insulator (GeOI) wafer, or a reconstructed wafer including semiconductor dies laterally encapsulated by an insulating encapsulant.

The chip probing apparatus 100 may further include a test head 140, a stiffener 150 and a circuit board 160, wherein the stiffener 150 is between the test head 140 and the circuit board 160, and the circuit board 160 is installed on the test head 140 by the stiffener 150. The probe card 110 is installed on the bottom surface of the circuit board 160, and the probe card 110 is electrically connected to the circuit board 160 through conductive bumps 170 (e.g., solder bumps). The probe card 110, the test head 140, the stiffener 150 and the circuit board 160 may be driven to move together if necessary. The test head 140 and the circuit board 160 are configured to apply and deliver a first testing signal to the shift detection pattern 200 through the shift detection needles 116a as well as receive a probing shift information (e.g., the prob card 110 is aligned or misaligned with the wafer 120, the shift amount between the shift detection pattern 200 and the shift detection needle 116a, and the shift direction) through the shift detection needles 116b. In other words, the test head 140 and the circuit board 160 are configured to apply and deliver the first testing signal to identify whether the shift detection needle 116a is pressed onto the target probing pattern (i.e., proper aligned), or the test head 140 and the circuit board 160 are configured to apply and deliver the first testing signal to identify whether the shift detection needle 116a is pressed onto the target probing pattern and the auxiliary pattern simultaneously (i.e., misaligned). If the probing shift information shows that the probe card and the wafer are misaligned, the probe card 110 and the wafer 130 need to be re-aligned. If the probing shift information shows that the probe card 110 is properly aligned with the wafer 120, the test head 140 and the circuit board 160 apply and deliver a second testing signal to the integrated circuit regions 132 through the electrical measurement needles 114 to obtain a chip probing information (e.g., known good die (KGD) information).

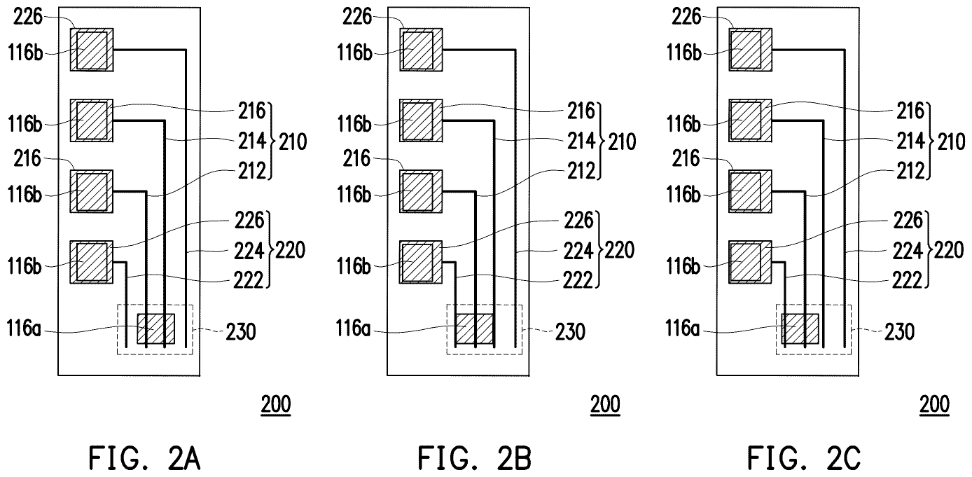

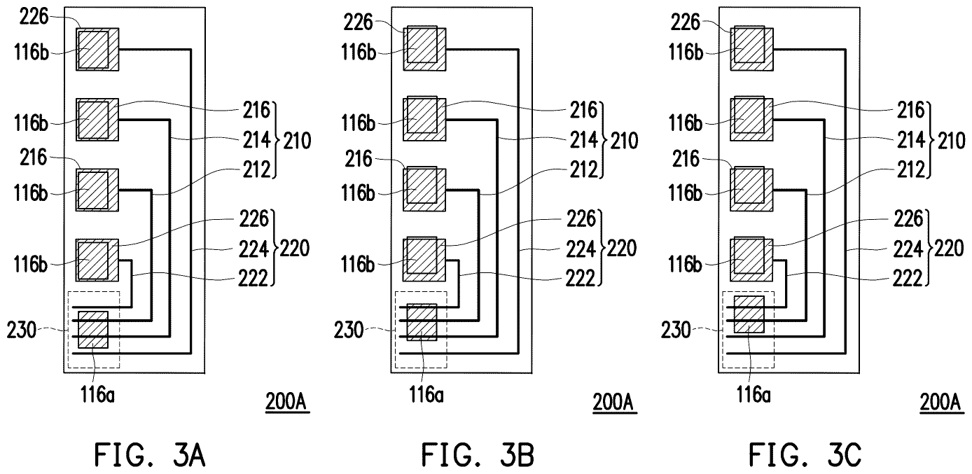

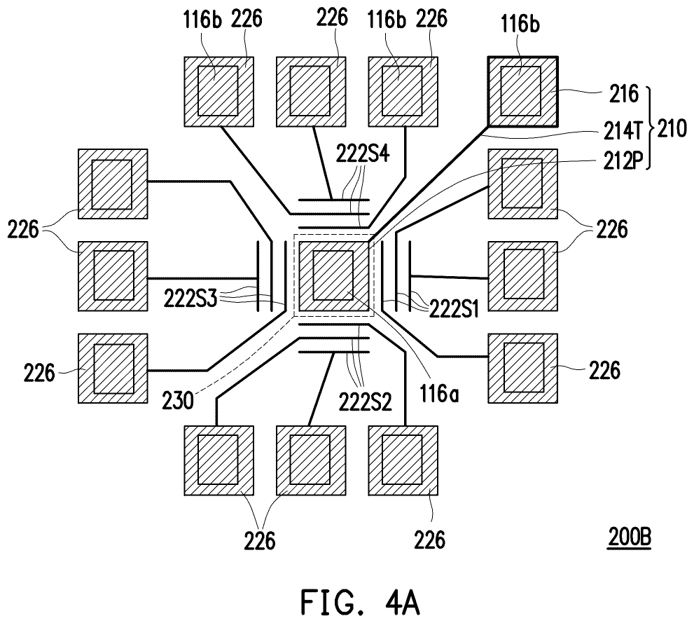

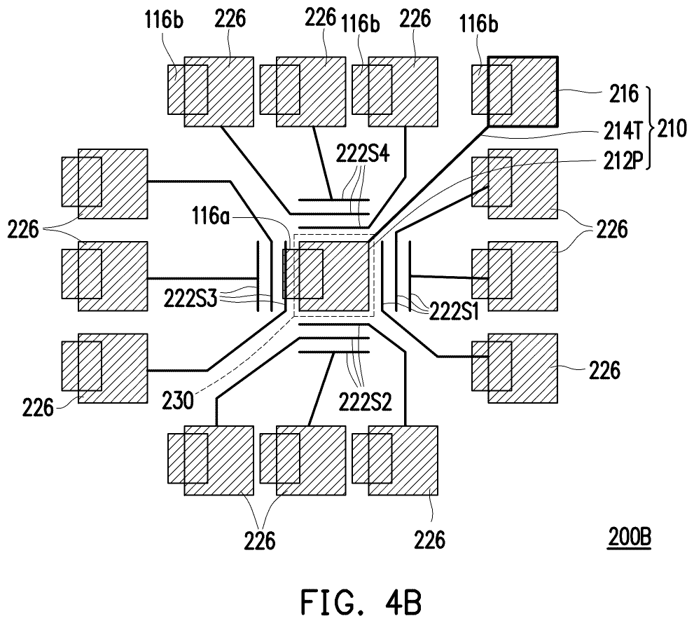

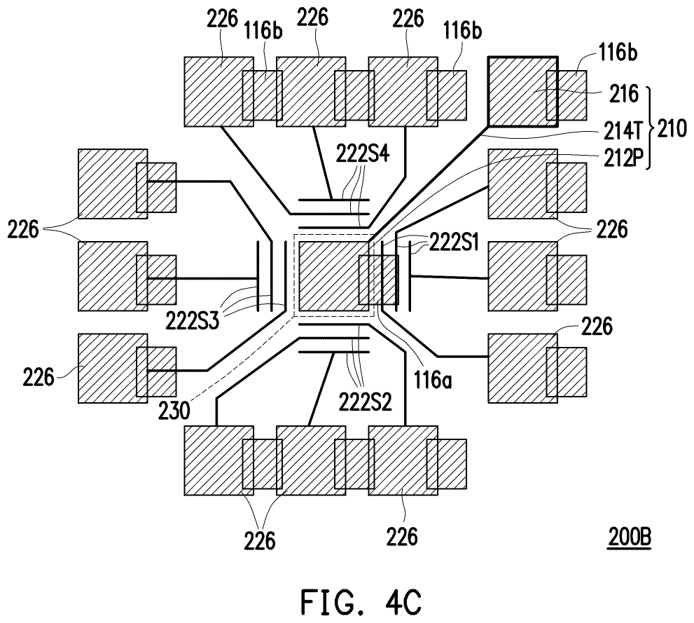

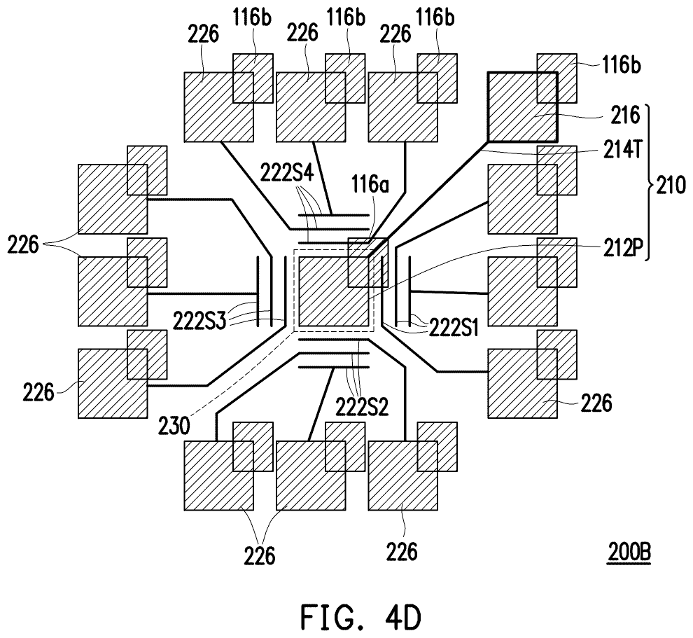

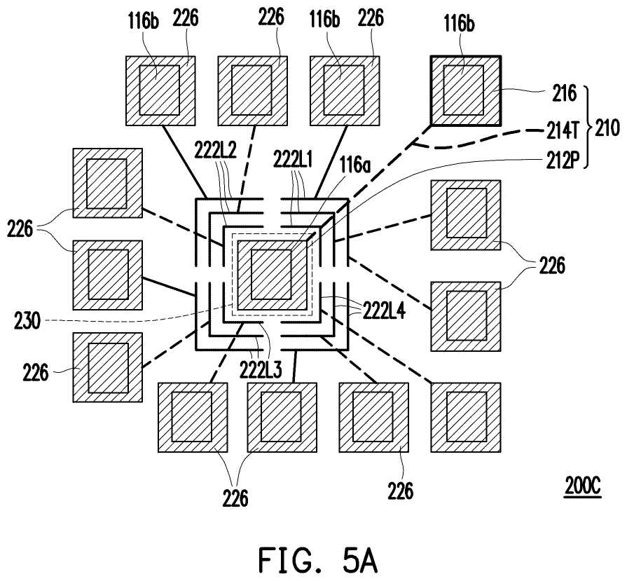

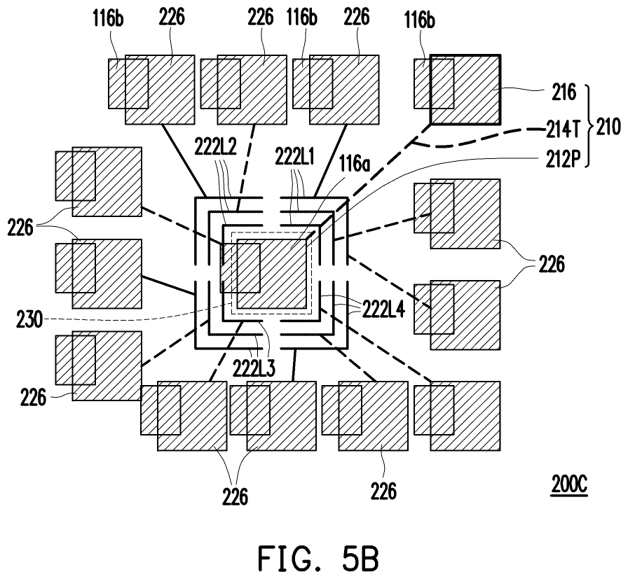

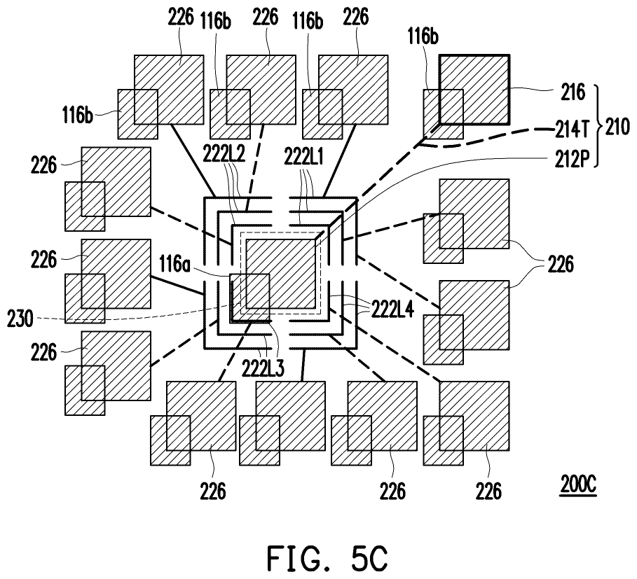

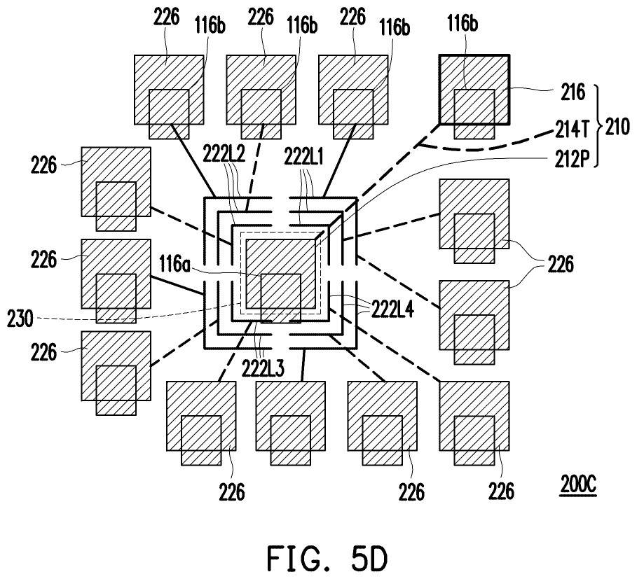

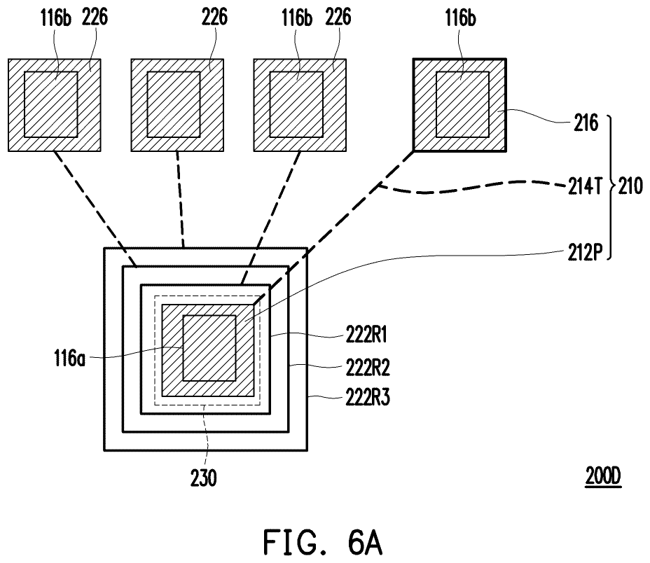

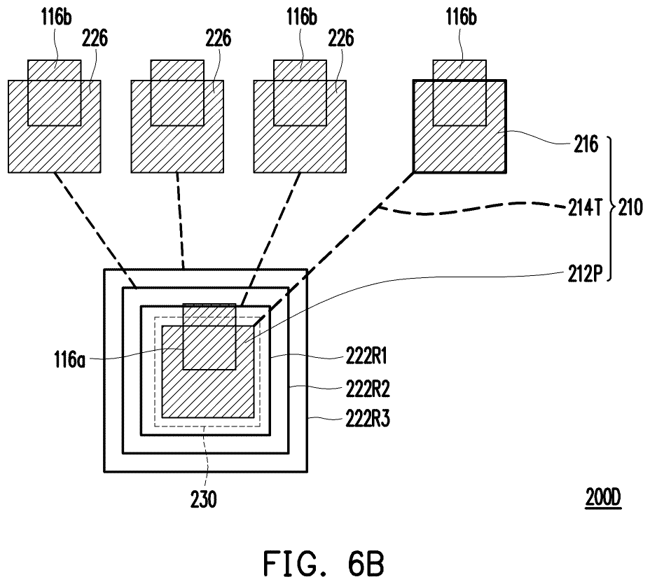

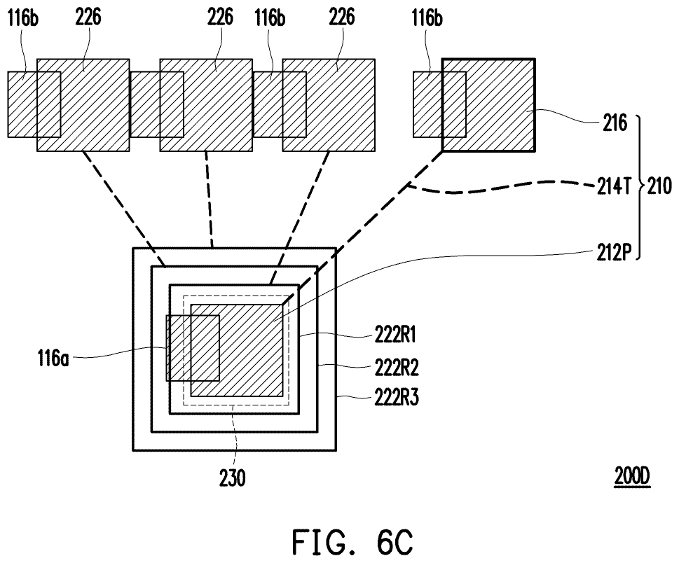

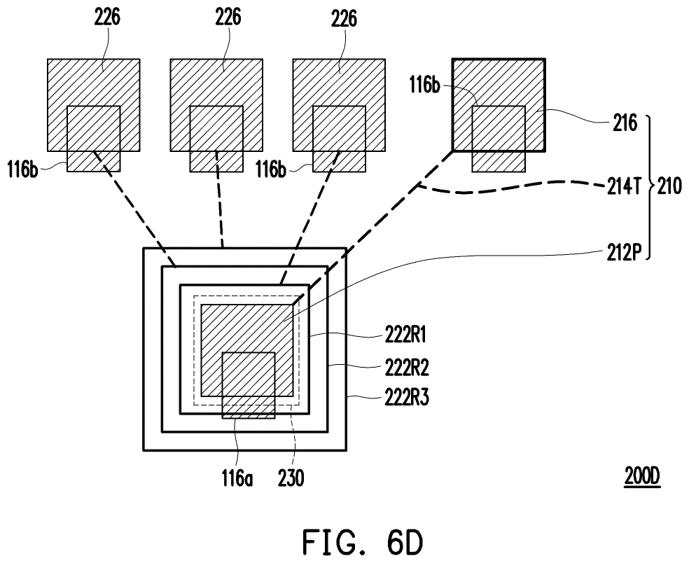

As shown in FIG. 1B, the wafer 130 includes integrated circuit regions 132 arranged in array, scribe line regions 134 and at least one shift detection pattern 200 distributed in the scribe line regions 134. The at least one shift detection pattern 200 may be or include at least one type of shift detection pattern which are illustrated in FIG. 2A through FIG. 2C, FIG. 3A through FIG. 3C, FIG. 4A through FIG. 4D, FIG. 5A through FIG. 5D, and FIG. 6A through FIG. 6D. The electrical measurement needles 114 of the probe card 110 are adapted to be pressed onto probing pads 132P on the integrated circuit regions 132 of the wafer 130, and the shift detection needles 116a and 116b of the probe card 110 are adapted to be pressed onto the shift detection pattern 200 of the wafer 130. The details of the shift detection pattern 200 on the wafer 130 as well as the shift detection procedure will be described in accompany with FIG. 2A through FIG. 2C, FIG. 3A through FIG. 3C, FIG. 4A through FIG. 4D, FIG. 5A through FIG. 5D, and FIG. 6A through FIG. 6D.

FIG. 2A schematically illustrates a top view of a shift detection pattern 200 when the shift detection needles 116a and 116b properly aligned in accordance with the first embodiment of the present disclosure.

Referring to FIG. 1A, FIG. 1B and FIG. 2A, in the present embodiments, the shift detection pattern 200 includes a target probing pattern 210 and an auxiliary pattern 220 distributed in proximity to the target probing pattern 210, wherein the lateral dimension (e.g., about 50 micrometers) of the shift detection needle 116a is greater than a minimum spacing between the target probing pattern 210 and the auxiliary pattern 220. The target probing pattern 210 includes a first target probing trace 212, a second target probing trace 214 and first readout probing pads 216 connected to the first ends of the first target probing trace 212 and the second target probing trace 214. The auxiliary pattern 220 includes a first auxiliary trace 222, a second auxiliary trace 224 and second readout probing pads 226 connected to the first ends of the first auxiliary trace 222 and the second auxiliary trace 224. The second end of the first target probing trace 212, a second end of the second target probing trace 214, the second end of the first auxiliary trace 222 and the second end of the second auxiliary trace 224 are distributed within the probing region 230 of the shift detection pattern 200. As illustrated in FIG. 2A, within the probing region 230 of the shift detection pattern 200, the first target probing trace 212, the second target probing trace 214, the first auxiliary trace 222 and the second auxiliary trace 224 extend vertically. Misalignment in horizontal direction may be detected by the shift detection pattern 200 accurately. Within the probing region 230 of the shift detection pattern 200, the first target probing trace 212, the second target probing trace 214, the first auxiliary trace 222 and the second auxiliary trace 224 may be substantial identical in linewidth (e.g., about 5 micrometers). Furthermore, within the probing region 230 of the shift detection pattern 200, the first auxiliary trace 222, the first target probing trace 212, the second target probing trace 214 and the second auxiliary trace 224 are arranged at equal intervals (e.g., about 25 micrometers) in the horizontal direction. In other words, the spacing between the first target probing trace 212 and the second target probing trace 214 substantially equals to the spacing between the second target probing trace 214 and the second auxiliary trace 224 as well as the spacing between the first target probing trace 212 and the first auxiliary trace 222. In some embodiments, the lateral dimension (e.g., about 50 micrometers) of the shift detection needle 116 a is twice the equal intervals between the first auxiliary trace 222, the first target probing trace 212, the second target probing trace 214 and the second auxiliary trace 224 (e.g., about 25 micrometers).

As illustrated in FIG. 2A, when the shift detection needle 116a is properly aligned with and pressed on the probing region 230 of the shift detection pattern 200, the shift detection needle 116a is pressed on and electrically connected to the first target probing trace 212 and the second target probing trace 214 simultaneously, the shift detection needle 116a is not electrically connected to the first auxiliary trace 222 and the second auxiliary trace 224, and meanwhile the shift detection needles 116b are pressed on and electrically connected to the first readout probing pads 216 and the second readout probing pads 226. When the shift detection needle 116a is properly aligned with and pressed on the probing region 230 of the shift detection pattern 200, the first testing signal applied and delivered from the test head 140 and the circuit board 160 (shown in FIG. 1A) is input to the shift detection pattern 200 through the shift detection needle 116a, and the first testing signal is transmitted to the first target probing trace 212 and the second target probing trace 214 such that the test head 140 (shown in FIG. 1A) can receive or readout the feedback of the first testing signal through the first readout probing pads 216 and two of the shift detection needles 116b which are pressed on the first readout probing pads 216.

FIG. 2B and FIG. 2C schematically illustrate top views of a shift detection pattern when the shift detection needle is misaligned in accordance with the first embodiment of the present disclosure.

Referring to FIG. 2B, when the shift detection needle 116a is offset to the left, the shift detection needle 116a may be pressed on and electrically connected to the first auxiliary trace 222, the first target probing trace 212 and the second target probing trace 214 simultaneously, the shift detection needle 116a is electrically insulated from the second auxiliary trace 224, and meanwhile the shift detection needles 116b are pressed on and electrically connected to the first readout probing pads 216 and the second readout probing pads 226. As illustrated in FIG. 2B, when the shift detection needle 116a is misaligned with and pressed on the probing region 230 of the shift detection pattern 200, the first testing signal applied and delivered from the test head 140 and the circuit board 160 (shown in FIG. 1A) is input to the shift detection pattern 200 through the shift detection needle 116a, and the first testing signal is transmitted to the first auxiliary trace 222, the first target probing trace 212 and the second target probing trace 214 such that the test head 140 (shown in FIG. 1A) can receive or readout the feedback of the first testing signal through the first readout probing pads 216, one of the second readout probing pads 226 connected to the first auxiliary trace 222 as well as two of the shift detection needles 116b pressed on the first readout probing pads 216.

The probing shift detection accuracy of the shift detection pattern 200 relates to the lateral dimension of the shift detection needle 116a, the linewidth of the first target probing trace 212, the second target probing trace 214, the first auxiliary trace 222 and the second auxiliary trace 224 as well as the equal intervals between the first auxiliary trace 222, the first target probing trace 212, the second target probing trace 214 and the second auxiliary trace 224. When the lateral dimension of the shift detection needle 116a is twice the equal intervals between the first auxiliary trace 222, the first target probing trace 212, the second target probing trace 214 and the second auxiliary trace 224, the probing shift detection accuracy of the shift detection pattern 200 may be calculated by followings equation: L_{S}=(L_{G}−L_{M})*0.5, wherein L_{S} represents the probing shift detection accuracy of the shift detection pattern 200; L_{G} represents the equal intervals (e.g., about 25 micrometers) between the first auxiliary trace 222, the first target probing trace 212, the second target probing trace 214 and the second auxiliary trace 224; and L_{M} represents the linewidth (e.g., about 5 micrometers) of the first target probing trace 212, the second target probing trace 214, the first auxiliary trace 222 and the second auxiliary trace 224. For example, the probing shift detection accuracy (L_{S}) of the shift detection pattern 200 is about 10 micrometers, when the equal intervals (L_{G}) between the first auxiliary trace 222, the first target probing trace 212, the second target probing trace 214 and the second auxiliary trace 224 is about 25 micrometers, the lateral dimension (W) of the shift detection needle 116a is about 50 micrometers (W=2*L_{G}), and the linewidth (L_{M}) of the first target probing trace 212, the second target probing trace 214, the first auxiliary trace 222 and the second auxiliary trace 224 is about 5 micrometers.

Referring to FIG. 2C, when the shift detection needle 116a is offset to the left further, the shift detection needle 116a may be pressed on and electrically connected to the first auxiliary trace 222 and the first target probing trace 212 simultaneously, the shift detection needle 116a is electrically insulated from the second target probing trace 214 and the second auxiliary trace 224, and meanwhile the shift detection needles 116b are pressed on and electrically connected to the first readout probing pads 216 and the second readout probing pads 226. As illustrated in FIG. 2C, when the shift detection needle 116a is misaligned with and pressed on the probing region 230 of the shift detection pattern 200, the first testing signal applied and delivered from the test head 140 and the circuit board 160 (shown in FIG. 1A) is input to the shift detection pattern 200 through the shift detection needle 116a, and the first testing signal is transmitted to the first auxiliary trace 222 and the first target probing trace 212 such that the test head 140 (shown in FIG. 1A) can receive or readout the feedback of the first testing signal through one of the first readout probing pads 216 connected to the first target probing trace 212 and one of the second readout probing pads 226 connected to the first auxiliary trace 222.

FIG. 3A schematically illustrates a top view of a shift detection pattern when the shift detection needles are properly aligned in accordance with the second embodiment of the present disclosure. FIG. 3B and FIG. 3C schematically illustrate top views of a shift detection pattern when the shift detection needle is misaligned in accordance with the second embodiment of the present disclosure.

Referring to FIG. 2A through 2C and FIG. 3A through 3C, a shift detection pattern 200A illustrated in FIG. 3A is similar to the shift detection pattern 200 illustrated in FIG. 2A except that the first target probing trace 212, the second target probing trace 214, the first auxiliary trace 222 and the second auxiliary trace 224 extend horizontally within the probing region 230 of the shift detection pattern 200A. Accordingly, misalignment in vertical direction may be detected by the shift detection pattern 200A accurately.

FIG. 4A schematically illustrates a top view of a shift detection pattern when the shift detection needles are properly aligned in accordance with the third embodiment of the present disclosure.

Referring to FIG. 1A, FIG. 1B and FIG. 4A, in the present embodiments, the shift detection pattern 200B includes a target probing pattern 210 and an auxiliary pattern 220 distributed in proximity to the target probing pattern 210, wherein the lateral dimension (e.g., about 50 micrometers) of the shift detection needle 116a is greater than a minimum spacing between the target probing pattern 210 and the auxiliary pattern 220. The target probing pattern 210 includes a target probing pad 212P, a connection trace 214T and a first readout probing pad 216, the auxiliary pattern 220 includes strip auxiliary traces 222S1, 222S2, 222S3 and 222S4 surrounding the target probing pad 212P, and each of the strip auxiliary traces 222S1, 222S2, 222S3 and 222S4 is connected to one of the second readout probing pads 226 respectively. For example, the first readout probing pad 216 is electrically connected to the target probing pad 212P through the connection trace 214T. As illustrated in FIG. 4A, only the target probing pad 212P is disposed within the probing region 230 of the shift detection pattern 200B. Misalignment in various directions (e.g., horizontal direction, vertical direction and so on) may be detected by the shift detection pattern 200B.

The first readout probing pad 216, the second readout probing pads 226 as well as the strip auxiliary traces 222S1, 222S2, 222S3 and 222S4 are distributed outside the probing region 230 of the shift detection pattern 200B. The strip auxiliary traces 222S1, 222S2, 222S3 and 222S4 may be substantial identical in linewidth (e.g., about 5 micrometers). The strip auxiliary traces 222S1, 222S2, 222S3 and 222S4 are arranged at equal intervals (e.g., about 25 micrometers). Furthermore, the minimum distance between the target probing pad 212P and the strip auxiliary traces 222S1, 222S2, 222S3 and 222S4 substantially equals to the equal intervals of the strip auxiliary traces 222S1, 222S2, 222S3 and 222S4.

As illustrated in FIG. 4A, when the shift detection needle 116a is properly aligned with and pressed on the probing region 230 of the shift detection pattern 200B, the shift detection needle 116a is pressed on and electrically connected to the target probing pad 212P only, the shift detection needle 116a is not electrically connected to the strip auxiliary traces 222S1, 222S2, 222S3 and 222S4 , and meanwhile the shift detection needles 116b are pressed on and electrically connected to the first readout probing pads 216 and the second readout probing pads 226. When the shift detection needle 116a is properly aligned with and pressed on the probing region 230 of the shift detection pattern 200B, the first testing signal applied and delivered from the test head 140 and the circuit board 160 (shown in FIG. 1A) is input to the shift detection pattern 200B through the shift detection needle 116a, and the first testing signal is transmitted to the target probing pad 212P such that the test head 140 (shown in FIG. 1A) can receive or readout the feedback of the first testing signal through the first readout probing pads 216 and one of the shift detection needles 116b which is pressed on the first readout probing pads 216.

FIG. 4B through FIG. 4D schematically illustrate top views of a shift detection pattern when the shift detection needle is misaligned in accordance with the third embodiment of the present disclosure.

Referring to FIG. 4B, when the shift detection needle 116a is offset to the left, the shift detection needle 116a may be pressed on and electrically connected to the target probing pad 212P and the strip auxiliary traces 222S3 simultaneously, the shift detection needle 116a is electrically insulated from the strip auxiliary traces 222S1, 222S2 and 222S4, and meanwhile the shift detection needles 116b are pressed on and electrically connected to the first readout probing pads 216 and the second readout probing pads 226. As illustrated in FIG. 4B, when the shift detection needle 116a is misaligned with and pressed on the probing region 230 of the shift detection pattern 200B, the first testing signal applied and delivered from the test head 140 and the circuit board 160 (shown in FIG. 1A) is input to the shift detection pattern 200B through the shift detection needle 116a, and the first testing signal is transmitted to the target probing pad 212P and the strip auxiliary traces 222S3 such that the test head 140 (shown in FIG. 1A) can receive or readout the feedback of the first testing signal through the first readout probing pads 216, one of the second readout probing pads 226 connected to the innermost strip auxiliary trace 222S3 as well as one of the shift detection needles 116b pressed on the innermost strip auxiliary trace 222S3.

Referring to FIG. 4C, when the shift detection needle 116a is offset to the right, the shift detection needle 116a may be pressed on and electrically connected to the target probing pad 212P and the strip auxiliary traces 222S1 simultaneously, the shift detection needle 116a is electrically insulated from the strip auxiliary traces 222S2, 222S3 and 222S4, and meanwhile the shift detection needles 116b are pressed on and electrically connected to the first readout probing pads 216 and the second readout probing pads 226. As illustrated in FIG. 4C, when the shift detection needle 116a is misaligned with and pressed on the probing region 230 of the shift detection pattern 200B, the first testing signal applied and delivered from the test head 140 and the circuit board 160 (shown in FIG. 1A) is input to the shift detection pattern 200B through the shift detection needle 116a, and the first testing signal is transmitted to the target probing pad 212P and the strip auxiliary traces 222S1 such that the test head 140 (shown in FIG. 1A) can receive or readout the feedback of the first testing signal through the first readout probing pads 216, two of the second readout probing pads 226 connected to two of the strip auxiliary traces 222S1 as well as two of the shift detection needles 116b pressed on the two strip auxiliary traces 222S1.

Referring to FIG. 4D, when the shift detection needle 116a is offset to the upper right, the shift detection needle 116a may be pressed on and electrically connected to the target probing pad 212P, the connection trace 214T and the strip auxiliary traces 222S1 and 222S4 simultaneously, the shift detection needle 116a is electrically insulated from the strip auxiliary traces 222S2 and 222S3, and meanwhile the shift detection needles 116b are pressed on and electrically connected to the first readout probing pads 216 and the second readout probing pads 226. As illustrated in FIG. 4D, when the shift detection needle 116a is misaligned with and pressed on the probing region 230 of the shift detection pattern 200B, the first testing signal applied and delivered from the test head 140 and the circuit board 160 (shown in FIG. 1A) is input to the shift detection pattern 200B through the shift detection needle 116a, and the first testing signal is transmitted to the target probing pad 212P and the strip auxiliary traces 222S1, 222S4 such that the test head 140 (shown in FIG. 1A) can receive or readout the feedback of the first testing signal through the first readout probing pads 216, two of the second readout probing pads 226 connected to the innermost strip auxiliary trace 222S1, the innermost strip auxiliary trace 222S4 as well as two of the shift detection needles 116b pressed on the two innermost strip auxiliary traces 222S1 and 222S4.

FIG. 5A schematically illustrates a top view of a shift detection pattern when the shift detection needles are properly aligned in accordance with the fourth embodiment of the present disclosure.

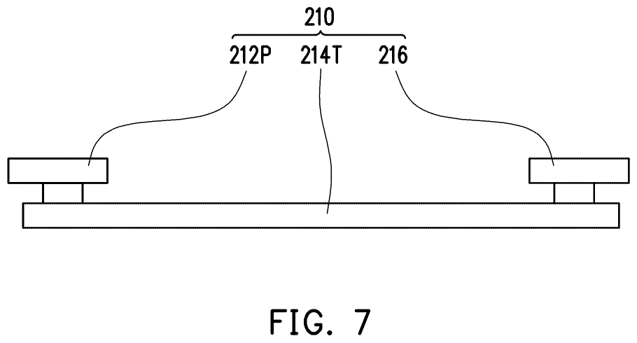

Referring to FIG. 1A, FIG. 1B and FIG. 5A, in the present embodiments, the shift detection pattern 200C includes a target probing pattern 210 and an auxiliary pattern 220 distributed in proximity to the target probing pattern 210, wherein the lateral dimension (e.g., about 50 micrometers) of the shift detection needle 116a is greater than a minimum spacing between the target probing pattern 210 and the auxiliary pattern 220. The target probing pattern 210 includes a target probing pad 212P, a connection trace 214T and a first readout probing pad 216, the auxiliary pattern 220 includes L-shaped auxiliary traces 222L1, 222L2, 222L3 and 222L4 surrounding the target probing pad 212P, and each of the L-shaped auxiliary traces 222L1, 222L2, 222L3 and 222L4 is connected to one of the second readout probing pads 226 respectively. For example, the first readout probing pad 216 is electrically connected to the target probing pad 212P through the connection trace 214T. As illustrated in FIG. 5A, only the target probing pad 212P is disposed within the probing region 230 of the shift detection pattern 200C. Misalignment in various directions (e.g., horizontal direction, vertical direction and so on) may be detected by the shift detection pattern 200C. It is noted that the target probing pattern 210 includes the target probing pad 212P, the connection trace 214T and the first readout probing pad 216 may be a multi-layered metallic structure illustrated in FIG. 7.

The first readout probing pad 216, the second readout probing pads 226 as well as the L-shaped auxiliary traces 222L1, 222L2, 222L3 and 222L4 are distributed outside the probing region 230 of the shift detection pattern 200C. The L-shaped auxiliary traces 222L1, 222L2, 222L3 and 222L4 may be substantial identical in linewidth (e.g., about 5 micrometers). The L-shaped auxiliary traces 222L1, 222L2, 222L3 and 222L4 are arranged at equal intervals (e.g., about 25 micrometers). Furthermore, the minimum distance between the target probing pad 212P and the L-shaped auxiliary traces 222L1, 222L2, 222L3 and 222L4 substantially equals to the equal intervals of the L-shaped auxiliary traces 222L1, 222L2, 222L3 and 222L4.

As illustrated in FIG. 5A, when the shift detection needle 116a is properly aligned with and pressed on the probing region 230 of the shift detection pattern 200C, the shift detection needle 116a is pressed on and electrically connected to the target probing pad 212P only, the shift detection needle 116a is not electrically connected to the L-shaped auxiliary traces 222L1, 222L2, 222L3 and 222L4, and meanwhile the shift detection needles 116b are pressed on and electrically connected to the first readout probing pads 216 and the second readout probing pads 226. When the shift detection needle 116a is properly aligned with and pressed on the probing region 230 of the shift detection pattern 200C, the first testing signal applied and delivered from the test head 140 and the circuit board 160 (shown in FIG. 1A) is input to the shift detection pattern 200C through the shift detection needle 116a, and the first testing signal is transmitted to the target probing pad 212P such that the test head 140 (shown in FIG. 1A) can receive or readout the feedback of the first testing signal through the first readout probing pads 216 and one of the shift detection needles 116b which is pressed on the first readout probing pads 216.

FIG. 5B through FIG. 5D schematically illustrate top views of a shift detection pattern when the shift detection needle is misaligned in accordance with the fourth embodiment of the present disclosure.

Referring to FIG. 5B, when the shift detection needle 116a is offset to the left, the shift detection needle 116a may be pressed on and electrically connected to the target probing pad 212P and the innermost L-shaped auxiliary traces 222L2 and 222L3 simultaneously, the shift detection needle 116a is electrically insulated from the strip auxiliary traces 222L1 and 222L4, and meanwhile the shift detection needles 116b are pressed on and electrically connected to the first readout probing pads 216 and the second readout probing pads 226. As illustrated in FIG. 5B, when the shift detection needle 116a is misaligned with and pressed on the probing region 230 of the shift detection pattern 200C, the first testing signal applied and delivered from the test head 140 and the circuit board 160 (shown in FIG. 1A) is input to the shift detection pattern 200C through the shift detection needle 116a, and the first testing signal is transmitted to the target probing pad 212P and the innermost L-shaped auxiliary traces 222L2, 222L3 such that the test head 140 (shown in FIG. 1A) can receive or readout the feedback of the first testing signal through the first readout probing pads 216, two of the second readout probing pads 226 connected to the innermost L-shaped auxiliary traces 222L2, 222L3 as well as two of the shift detection needles 116b pressed on the innermost L-shaped auxiliary traces 222L2, 222L3.

Referring to FIG. 5C, when the shift detection needle 116a is offset to the lower left, the shift detection needle 116a may be pressed on and electrically connected to the target probing pad 212P and the innermost L-shaped auxiliary trace 222L3 simultaneously, the shift detection needle 116a is electrically insulated from the L-shaped auxiliary traces 222L1, 222L2 and 222L4, and meanwhile the shift detection needles 116b are pressed on and electrically connected to the first readout probing pads 216 and the second readout probing pads 226. As illustrated in FIG. 5C, when the shift detection needle 116a is misaligned with and pressed on the probing region 230 of the shift detection pattern 200C, the first testing signal applied and delivered from the test head 140 and the circuit board 160 (shown in FIG. 1A) is input to the shift detection pattern 200C through the shift detection needle 116a, and the first testing signal is transmitted to the target probing pad 212P and the innermost L-shaped auxiliary traces 222L3 such that the test head 140 (shown in FIG. 1A) can receive or readout the feedback of the first testing signal through the first readout probing pads 216, one of the second readout probing pads 226 connected to the innermost L-shaped auxiliary trace 222L3 as well as one of the shift detection needles 116b pressed on the innermost L-shaped auxiliary trace 222L3.

Referring to FIG. 5D, when the shift detection needle 116a is offset downwards, the shift detection needle 116a may be pressed on and electrically connected to the target probing pad 212P and the innermost L-shaped auxiliary traces 222L3 and 222L4 simultaneously, the shift detection needle 116a is electrically insulated from the strip auxiliary traces 222L1 and 222L2, and meanwhile the shift detection needles 116b are pressed on and electrically connected to the first readout probing pads 216 and the second readout probing pads 226. As illustrated in FIG. 5D, when the shift detection needle 116a is misaligned with and pressed on the probing region 230 of the shift detection pattern 200C, the first testing signal applied and delivered from the test head 140 and the circuit board 160 (shown in FIG. 1A) is input to the shift detection pattern 200C through the shift detection needle 116a, and the first testing signal is transmitted to the target probing pad 212P and the innermost L-shaped auxiliary traces 222L3, 222L4 such that the test head 140 (shown in FIG. 1A) can receive or readout the feedback of the first testing signal through the first readout probing pads 216, two of the second readout probing pads 226 connected to the innermost L-shaped auxiliary traces 222L3, 222L4 as well as two of the shift detection needles 116b pressed on the innermost L-shaped auxiliary traces 222L3, 222L4.

FIG. 6A schematically illustrates a top view of a shift detection pattern when the shift detection needles are properly aligned in accordance with the fifth embodiment of the present disclosure.

Referring to FIG. 1A, FIG. 1B and FIG. 6A, in the present embodiments, the shift detection pattern 200D includes a target probing pattern 210 and an auxiliary pattern 220 distributed in proximity to the target probing pattern 210, wherein the lateral dimension (e.g., about 50 micrometers) of the shift detection needle 116a is greater than a minimum spacing between the target probing pattern 210 and the auxiliary pattern 220. The target probing pattern 210 includes a target probing pad 212P, a connection trace 214T and a first readout probing pad 216, the auxiliary pattern 220 includes the ring-shaped auxiliary traces 222R1, 222R2 and 222R3 surrounding the target probing pad 212P, and each of the ring-shaped auxiliary traces 222R1, 222R2 and 222R3 is connected to one of the second readout probing pads 226 respectively. For example, the first readout probing pad 216 is electrically connected to the target probing pad 212P through the connection trace 214T. As illustrated in FIG. 6A, only the target probing pad 212P is disposed within the probing region 230 of the shift detection pattern 200D. Shift amount of misalignment may be detected by the shift detection pattern 200D. It is noted that the target probing pattern 210 includes the target probing pad 212P, the connection trace 214T and the first readout probing pad 216 may be a multi-layered metallic structure illustrated in FIG. 7.

The first readout probing pad 216, the second readout probing pads 226 as well as the ring-shaped auxiliary traces 222R1, 222R2 and 222R3 are distributed outside the probing region 230 of the shift detection pattern 200D. The ring-shaped auxiliary traces 222R 1, 222R2 and 222R3 may be substantial identical in linewidth (e.g., about 5 micrometers). The ring-shaped auxiliary traces 222R1, 222R2 and 222R3 are arranged at equal intervals (e.g., about 25 micrometers). Furthermore, the minimum distance between the target probing pad 212P and the ring-shaped auxiliary trace 222R1 substantially equals to the equal intervals of the ring-shaped auxiliary traces 222R1, 222R2 and 222R3.

As illustrated in FIG. 6A, when the shift detection needle 116a is properly aligned with and pressed on the probing region 230 of the shift detection pattern 200D, the shift detection needle 116a is pressed on and electrically connected to the target probing pad 212P only, the shift detection needle 116a is not electrically connected to the ring-shaped auxiliary traces 222R1, 222R2 and 222R3, and meanwhile the shift detection needles 116b are pressed on and electrically connected to the first readout probing pads 216 and the second readout probing pads 226. When the shift detection needle 116a is properly aligned with and pressed on the probing region 230 of the shift detection pattern 200D, the first testing signal applied and delivered from the test head 140 and the circuit board 160 (shown in FIG. 1A) is input to the shift detection pattern 200C through the shift detection needle 116a, and the first testing signal is transmitted to the target probing pad 212P such that the test head 140 (shown in FIG. 1A) can receive or readout the feedback of the first testing signal through the first readout probing pads 216 and one of the shift detection needles 116b which is pressed on the first readout probing pads 216.

FIG. 6B through FIG. 6D schematically illustrate top views of a shift detection pattern when the shift detection needle is misaligned in accordance with the fifth embodiment of the present disclosure.

Referring to FIG. 6B through FIG. 6D, when the shift detection needle 116a is offset upwards, offset to the left or offset downwards, the shift detection needle 116a may be pressed on and electrically connected to the target probing pad 212P and the innermost ring-shaped auxiliary trace 222R1 simultaneously, the shift detection needle 116a is electrically insulated from the ring-shaped auxiliary trace 222R2 and 222R3, and meanwhile the shift detection needles 116b are pressed on and electrically connected to the first readout probing pads 216 and the second readout probing pads 226. As illustrated in FIG. 6B through FIG. 6D, when the shift detection needle 116a is misaligned with and pressed on the probing region 230 of the shift detection pattern 200D, the first testing signal applied and delivered from the test head 140 and the circuit board 160 (shown in FIG. 1A) is input to the shift detection pattern 200D through the shift detection needle 116a, and the first testing signal is transmitted to the target probing pad 212P and the innermost ring-shaped auxiliary trace 222R1 such that the test head 140 (shown in FIG. 1A) can receive or readout the feedback of the first testing signal through the first readout probing pads 216, one of the second readout probing pads 226 connected to the innermost ring-shaped auxiliary trace 222R1 as well as one of the shift detection needles 116b pressed on the innermost ring-shaped auxiliary trace 222R1.

In the above-mentioned embodiments, a chip probing apparatus and various chip probing process are discussed to provide good wafer probing quality gating by electric testing. Furthermore, since the shift detection patterns for shift detection can be fabricated in scribe line regions of wafers to be inspected, the fabrication of the shift detection patterns is compatible with current process, and the shift detection patterns will not impact customer DUT design area.

In accordance with some embodiments of the disclosure, a chip probing apparatus, adapted to perform a chip probing process of a wafer is provided. The wafer includes integrated circuit regions, scribe line regions and at least one shift detection pattern distributed in the scribe line regions. The chip probing apparatus includes a probe card including electrical measurement needles and shift detection needles, wherein the electrical measurement needles are adapted to be pressed onto the integrated circuit regions, and the shift detection needles are adapted to be pressed onto the shift detection pattern. The at least one shift detection pattern includes a target probing pattern and an auxiliary pattern distributed in proximity to the target probing pattern, and one of the shift detection needles is pressed onto the target probing pattern and the auxiliary pattern simultaneously when the probe card is misaligned with the wafer.

In accordance with some embodiments of the disclosure, a chip probing method is provided. A wafer including integrated circuit regions, scribe line regions and at least one shift detection pattern distributed in the scribe line regions is provided, wherein the at least one shift detection pattern includes a target probing pattern and auxiliary pattern distributed in proximity to the target probing pattern. A probe card is provided over the wafer, wherein the probe card includes electrical measurement needles and shift detection needles. The electrical measurement needles are pressed onto the integrated circuit regions and the shift detection needles are pressed onto the shift detection pattern. A first testing signal is applied to the shift detection pattern through the shift detection needles to obtain a probing shift information. A second testing signal is applied to the integrated circuit regions through the electrical measurement needles to obtain a chip probing information when the probing shift information shows that the probe card is aligned with the wafer.

In accordance with some alternative embodiments of the disclosure, a shift detection pattern for operating with a probe card having shift detection needles is provided. The shift detection pattern includes a target probing pattern and an auxiliary pattern distributed in proximity to and electrically insulated from the target probing pattern, wherein a minimum spacing between the target probing pattern and the auxiliary pattern is less than a lateral dimension of the shift detection needles.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A chip probing apparatus, adapted to perform a chip probing process of a wafer, the wafer comprising integrated circuit regions, scribe line regions and at least one shift detection pattern distributed in the scribe line regions, and the chip probing apparatus comprising:
a probe card comprising electrical measurement needles and shift detection needles, wherein the electrical measurement needles are adapted to be pressed onto the integrated circuit regions, and the shift detection needles are adapted to be pressed onto the shift detection pattern,
wherein the at least one shift detection pattern comprises a target probing pattern and an auxiliary pattern distributed in proximity to the target probing pattern, and one of the shift detection needles is pressed onto the target probing pattern and the auxiliary pattern simultaneously when the probe card is misaligned with the wafer.

2. The chip probing apparatus of claim 1,
wherein the target probing pattern comprises a first target probing trace, a second target probing trace and first readout probing pads connected to first ends of the first and second target probing traces, the auxiliary pattern comprises a first auxiliary trace, a second auxiliary trace and second readout probing pads connected to first ends of the first and second auxiliary traces, and
wherein second ends of the first and second target probing traces as well as second ends of the first and second auxiliary traces are in a probing region of the at least one shift detection pattern.

3. The chip probing apparatus of claim 2, wherein the first target probing trace, the second target probing trace, the first auxiliary trace and second auxiliary trace extend vertically in the probing region.

4. The chip probing apparatus of claim 2, wherein the first target probing trace, the second target probing trace, the first auxiliary trace and second auxiliary trace extend horizontally in the probing region.

5. The chip probing apparatus of claim 1,
wherein the target probing pattern comprises a target probing pad and a first readout probing pad connected to the target probing pad, and
wherein the auxiliary pattern comprises auxiliary traces surrounding the target probing pad and second readout probing pads connected to the auxiliary traces.

6. The chip probing apparatus of claim 5, wherein the auxiliary traces comprise ring-shaped auxiliary traces surrounding the target probing pad, and each of the ring-shaped auxiliary traces is connected to one of the second readout probing pads respectively.

7. The chip probing apparatus of claim 5, wherein the auxiliary traces comprise strip auxiliary traces disposed around the target probing pad, and each of the strip auxiliary traces is connected to one of the second readout probing pads respectively.

8. The chip probing apparatus of claim 5, wherein the auxiliary traces comprise L-shaped auxiliary traces disposed around the target probing pad, and each of the L-shaped auxiliary traces is connected to one of the second readout probing pads respectively.

9. The chip probing apparatus of claim 1, wherein a lateral dimension of the shift detection needles is greater than a minimum spacing between the target probing pattern and the auxiliary pattern.

10. A chip probing method, comprising:
providing a wafer comprising integrated circuit regions, scribe line regions and at least one shift detection pattern distributed in the scribe line regions, wherein the at least one shift detection pattern comprises a target probing pattern and an auxiliary pattern distributed in proximity to the target probing pattern;
providing a probe card over the wafer, the probe card comprising electrical measurement needles and shift detection needles; and
pressing the electrical measurement needles onto the integrated circuit regions and pressing the shift detection needles onto the shift detection pattern;
applying a first testing signal to the shift detection pattern through the shift detection needles to obtain a probing shift information; and
applying a second testing signal to the integrated circuit regions through the electrical measurement needles to obtain a chip probing information when the probing shift information shows that the probe card is aligned with the wafer.

11. The chip probing method of claim 10, wherein the probing shift information comprises a shift amount between the shift detection pattern and the shift detection needles as well as a shift direction between the shift detection pattern and the shift detection needles.

12. The chip probing method of claim 10, wherein the first testing signal is applied to the shift detection pattern through the shift detection needles to identify whether one of the shift detection needles is pressed onto the target probing pattern and the auxiliary pattern simultaneously.

13. The chip probing method of claim 10,
wherein the target probing pattern comprises a first target probing trace, a second target probing trace and first readout probing pads connected to first ends of the first and second target probing traces, the auxiliary pattern comprises a first auxiliary trace, a second auxiliary trace and second readout probing pads connected to first ends of the first and second auxiliary traces,
wherein second ends of the first and second target probing traces as well as second ends of the first and second auxiliary traces are in a probing region of the at least one shift detection pattern, and
wherein the first testing signal is applied to the shift detection pattern through the shift detection needles to identify whether one of the shift detection needles is pressed onto the first target probing trace and the first auxiliary trace simultaneously.

14. The chip probing method of claim 10,
wherein the target probing pattern comprises a target probing pad and a first readout probing pad connected to the target probing pad,
wherein the auxiliary pattern comprises auxiliary traces surrounding the target probing pad and second readout probing pads connected to the auxiliary traces, and
wherein the first testing signal is applied to the shift detection pattern through the shift detection needles to identify whether one of the shift detection needles is pressed onto the target probing pad and the auxiliary traces simultaneously.

15. The chip probing method of claim 10,
wherein the target probing pattern comprises a target probing pad and a first readout probing pad connected to the target probing pad,
wherein the auxiliary pattern comprises auxiliary traces surrounding the target probing pad and second readout probing pads connected to the auxiliary traces, and
wherein the first testing signal is applied to the shift detection pattern through the shift detection needles to identify which one of the auxiliary traces is pressed by the shift detection needles.

16. The chip probing method of claim 10 further comprising:
re-aligning the probe card and the wafer when the probing shift information shows that the probe card and the wafer are misaligned.

17. A shift detection pattern for operating with a probe card having shift detection needles, and the shift detection pattern comprising:
a target probing pattern; and
an auxiliary pattern distributed in proximity to and electrically insulated from the target probing pattern, wherein a minimum spacing between the target probing pattern and the auxiliary pattern is less than a lateral dimension of the shift detection needles.

18. The shift detection pattern of claim 17, wherein the target probing pattern comprises a pair of target probing traces, and the auxiliary pattern comprise comprises auxiliary traces disposed at opposite sides of the pair of target probing traces.

19. The shift detection pattern of claim 17, wherein the target probing pattern comprises a target probing pad.

20. The shift detection pattern of claim 19, wherein the auxiliary traces comprise ring-shaped auxiliary traces, strip auxiliary traces or L-shaped auxiliary traces disposed around the target probing pad, and each of the auxiliary traces is connected to one of the second readout probing pads respectively.
